(19) United States
(12) Patent Application Publication
(10) Pub. No.: US 2026/0043877 A1
(43) Pub. Date: Feb. 12, 2026

(54) ACCESSORY IDENTIFICATION METHOD AND DEVICE, AND STORAGE MEDIUM

(71) Applicant: AAC ACOUSTIC TECHNOLOGIES (SHENZHEN) CO., LTD., Shenzhen (CN)

(72) Inventors: Hongyan Tao, Shenzhen (CN); Maoxi Qin, Shenzhen (CN)

(21) Appl. No.: 19/006,248

(22) Filed: Dec. 31, 2024

Related U.S. Application Data
(63) Continuation of application No. PCT/CN2024/110550, filed on Aug. 8, 2024.

(51) Int. Cl. G01R 33/07; G01R 33/00

(52) U.S. Cl. CPC G01R 33/07; G01R 33/0023

(57) ABSTRACT

An accessory identification method includes: generating target magnetic intensity characterization data by the magnetic intensity detection element in response to a magnetic intensity of a magnetic component in a target accessory, when it is detected that the target accessory is located at a preset target position of the electronic device; matching the target magnetic intensity characterization data with a preset accessory index table; and determining accessory identification information corresponding to a matched magnetic field intensity characterization data range as identification information of the target accessory. According to the present disclosure, the identification information of the accessory can be hidden, which is conductive to achieving the security of the accessory information. Meanwhile, excessive detection devices is not required and thus the volume occupied by hardware can be reduced, thereby saving the hardware resource cost.

### TECHNICAL FIELD

The present disclosure relates to the technical field of electronics, and in particular, to an accessory identification method, an accessory identification device and a storage medium.

### BACKGROUND

In recent years, various electronic products have become more and more functional, and the categories of accessories/attachments produced for implementing various functions have been increasing. In order to better adapt and deploy individual differences of different types of accessories, it is necessary to know the association information of various accessories. In the related art, the association information of the accessories is usually identified in a manner of adding a two-dimensional code or a bar code to the accessory and reading information of the two-dimensional code or the bar code by an electronic device with a camera or a scanning gun to identify the accessory, or in a manner of adding an NFC (RFID) tag to the accessory and reading the accessory information by an NFC (RFID) card reader installed in the electronic device. In the manner of identifying a two-dimensional code, since a camera or a scanning gun is needed, and the camera or the scanning gun occupies large resources, the requirement for system resources is high, and the two-dimensional code/bar code of the accessory is exposed and thus prone to be copied and stolen. In the manner of NFC (RFID) tag reading, the electronic device and the accessory both need a certain antenna size area. Meanwhile, the cost of a card reader at the electronic device end is high, the power consumption of the card reader will be high if the card reader is turned on for a long time. The card reader can affect the user experience when turned on if the card reader is not turned on for a long time.

### SUMMARY

The main purpose of the present disclosure is to provide an accessory identification method, an accessory identification device and a storage medium, which can at least solve following problems in the related art: the accessory identification method requires high hardware resource cost or is unbeneficial to achieving the security of the accessory information.

In order to achieve the above purposes, a first aspect of the present disclosure provides an accessory identification method. The accessory identification method is applied to an electronic device provided with a magnetic field intensity detection element. The accessory identification includes:
generating target magnetic intensity characterization data by the magnetic intensity detection element in response to a magnetic intensity of a magnetic component in a target accessory, when it is detected that the target accessory is located at a preset target position of the electronic device, wherein the magnetic intensity characterization data comprise voltage data;
matching the target magnetic field intensity characterization data with a preset accessory index table, wherein the accessory index table comprises a mapping relationship between a magnetic field intensity characterization data range and accessory identification information; and
determining accessory identification information corresponding to a matched magnetic field intensity characterization data range as identification information of the target accessory.

As an improvement, prior to generating the target magnetic field intensity characterization data by the magnetic field intensity detection element in response to the magnetic field intensity of the magnetic component in the target accessory, the method further comprises:
detecting the magnetic field intensity of the magnetic component in the target accessory in real time by the magnetic field intensity detection element to obtain respective first voltage data; and
determining that the target accessory is located at a preset target position of the electronic device when the first voltage data are within a preset voltage threshold range.

As an improvement, subsequent to matching the target magnetic field intensity characterization data with the preset accessory index table, the method further comprises:
outputting prompt information that the target accessory is in an abnormal state when the target magnetic field intensity characterization data does not match a respective magnetic field intensity characterization data range in the accessory index table.

As an improvement, a plurality of target magnetic field intensity characterization data is provided, and said matching the target magnetic field intensity characterization data with the preset accessory index table comprises:
screening a plurality of target voltage data to obtain a plurality of first target voltage data;
calculating an average value of the plurality of first target voltage data to obtain second target voltage data; and
matching the second target voltage data with the preset accessory index table.

As an improvement, said screening the plurality of target voltage data to obtain the plurality of first target voltage data comprises:
calculating to obtain a sum of absolute values of differences between each of the plurality of target voltage data and the remaining target voltage data;
comparing each of the sums of absolute values with a preset threshold; and
removing respective target voltage data to obtain the plurality of first target voltage data when existing at least one sum of target absolute values greater than the preset threshold.

As an improvement, the magnetic field intensity detection element comprises a Hall sensor, and said generating target magnetic field intensity characterization data by the magnetic field intensity detection element in response to the magnetic field intensity of the magnetic component in the target accessory comprises:
detecting magnetic field intensity of the magnetic components in the target accessory by the Hall sensor when the target accessory is in different orientations to obtain the plurality of target magnetic field intensity characterization data; and/or
detecting a magnetic field intensity of a magnetic component in the target accessory in a same orientation by the Hall sensor according to preset times of detection to obtain the plurality of target magnetic field intensity characterization data.

As an improvement, prior to the generating target magnetic field intensity characterization data by the magnetic field intensity detection element in response to the magnetic field intensity of the magnetic component in the target accessory, the method further comprises:
detecting a magnetic field intensity of a reference magnetic component in a reference accessory at the target position by on the magnetic field intensity detection element to obtain reference magnetic field intensity characterization data; and
performing said generating target magnetic field intensity characterization data by the magnetic field intensity detection element in response to the magnetic field intensity of the magnetic component in the target accessory, when the reference magnetic field intensity characterization data satisfies a magnetic field intensity characterization data range associated with the reference magnetic component.

A second aspect of the present disclosure provides an accessory identification device applied to an electronic device provided with a magnetic field intensity detection element. The accessory identification device includes:
a generation module configured to generate target magnetic field intensity characterization data by the magnetic field intensity detection element in response to a magnetic field intensity of a magnetic component in a target accessory, when it is detected that a target accessory is located at a preset target position of the electronic device, wherein the magnetic field intensity characterization data comprise voltage data;
a matching module configured to match the target magnetic field intensity characterization data with a preset accessory index table, wherein the accessory index table comprises a mapping relationship between a magnetic field intensity characterization data range and accessory identification information; and
a determining module configured to determine accessory identification information corresponding to a matched magnetic field intensity characterization data range as identification information of the target accessory.

A third aspect of the present disclosure provides an electronic device. The electronic device includes:
a memory; and
a processor configured to execute a computer program stored in the memory;
wherein when executing the computer program, the processor implements the steps of the accessory identification method as mentioned above.

A fourth aspect of the present disclosure provides a computer readable storage medium storing a computer program. The computer program, when executed by a processor, implements the steps of the accessory identification method as mentioned above.

It can be seen that, with the accessory identification method and device and the storage medium according to the present disclosure, when it is detected that the target accessory is located at the preset target position of the electronic device, the target magnetic intensity characterization data is generated by the magnetic intensity detection element in response to the magnetic intensity of the magnetic component in the target accessory. The magnetic intensity characterization data includes voltage data. The target magnetic intensity characterization data is matched with a preset accessory index table. The accessory index table includes a mapping relationship between the magnetic intensity characterization data range and the accessory identification information. The accessory identification information corresponding to the matched magnetic intensity characterization data range is determined as the identification information of the target accessory. According to the implementation of the technical solutions of the present disclosure, the magnetic field intensity of the magnetic component in the accessory is detected to obtain the respective magnetic intensity characterization data. Then the identification information of the accessory can be obtained by querying in the table according to the magnetic intensity characterization data, so that the identification information of the accessory can be hidden in the identification mode, thereby achieving the security of the accessory information. Meanwhile, compared with the related art, the present disclosure only needs the magnetic intensity detection element installed on the electronic device and the magnetic component installed on the accessory, without excessive hardware resources, thereby effectively saving the hardware resource cost.

### BRIEF DESCRIPTION OF DRAWINGS

Many aspects of the exemplary embodiment can be better understood with reference to following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a general flowchart diagram of an accessory identification method according to an embodiment of the present disclosure;

FIG. 2 is a detailed flowchart diagram of an accessory identification method according to an embodiment of the present disclosure;

FIG. 3 is a schematic diagram of a magnetic intensity detection principle according to an embodiment of the present disclosure;

FIG. 4 is a schematic diagram of a first type of accessory identification according to an embodiment of the present disclosure;

FIG. 5 is a schematic diagram of a second type of accessory identification according to an embodiment of the present disclosure;

FIG. 6 is a schematic diagram of a third type of accessory identification according to an embodiment of the present disclosure;

FIG. 7 is a schematic diagram of modules of an accessory identification device according to an embodiment of the present disclosure; and

FIG. 8 is a schematic structural diagram of an electronic device according to an embodiment of the present disclosure.

### DESCRIPTION OF EMBODIMENTS

In order to more clearly illustrate objectives, technical solutions, and advantages of the embodiments of the present disclosure, the technical solutions in the embodiments of the present disclosure are clearly and completely described in details with reference to the accompanying drawings. The described embodiments are merely part of the embodiments of the present disclosure rather than all of the embodiments. All other embodiments obtained by those skilled in the art based on the embodiments of the present disclosure shall fall into the protection scope of the present disclosure.

In addition, the terms “first” and “second” are merely used for descriptive purposes, and should not be understood as indicating or implying relative importance or implicitly indicating the quantity of the indicated technical features. Therefore, a feature defined by “first” and “second” can indicate or imply to include one or more of the feature. In the description of embodiments of the present disclosure, “a plurality of” means two or more, unless specifically limited otherwise.

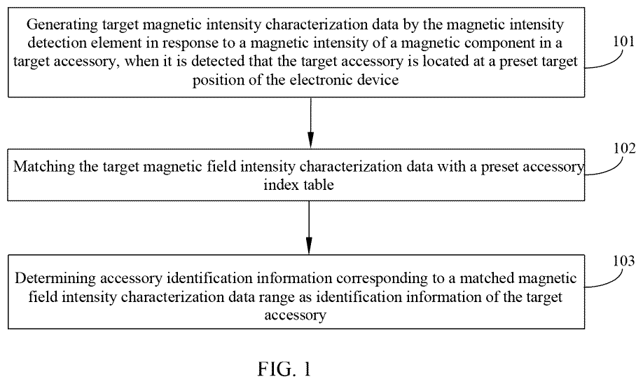

In order to solve the problem in the related art that the accessory identification method requires high hardware resource cost or is unbeneficial to achieving the security of the accessory information, the first embodiment of the present disclosure provides an accessory identification method, which is applied to an electronic device, and the electronic device is provided with a magnetic intensity detection element. The magnetic intensity detection element can be an element integrated with the electronic device itself, or can be an element additionally installed during detection. The magnetic intensity detection element can be a Hall sensor or other sensor having a magnetic field intensity detection function. In this embodiment, a linear Hall sensor is taken as an example for description. FIG. 1 is a general flowchart diagram of an accessory identification method according to an embodiment. The accessory identification method includes steps 101 to 103.

Step 101: when it is detected that the target accessory is located at a preset target position of the electronic device, the target magnetic field intensity characterization data is generated by the magnetic field intensity detection element in response to the magnetic field intensity of the magnetic component in a target accessory.

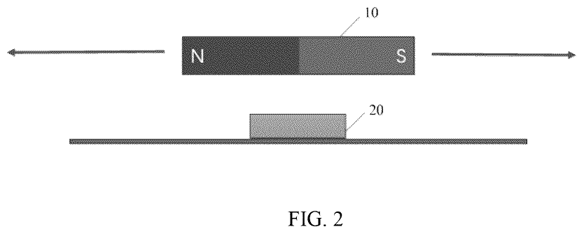

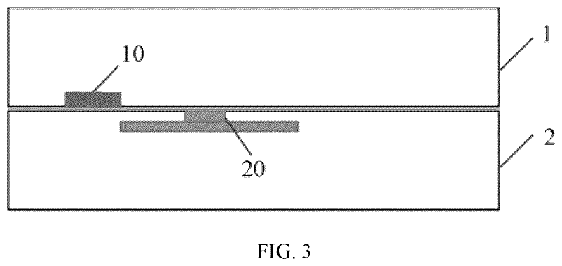

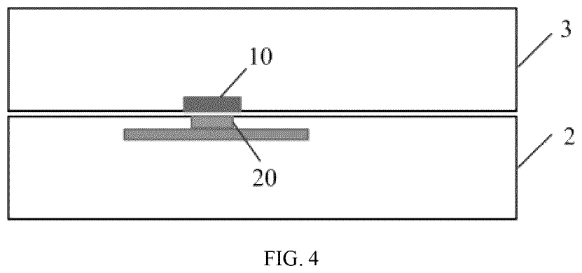

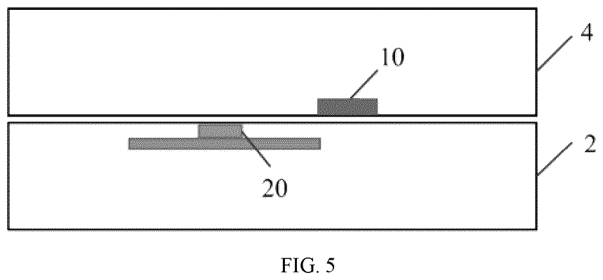

In an embodiment, accessory identification is performed based on magnetic field intensity detection, and the magnetic field intensity detection can be performed by using a linear Hall sensor. FIG. 2 is a schematic structural diagram showing the magnetic field intensity detection principle, when a position of a magnet 10 changes, a magnetic field intensity detected by a Hall sensor 20 also changes, and accordingly, the output magnetic field intensity characterization data also changes. Therefore, a magnetic component such as a magnet can be disposed in different accessories, so that when different accessories are located at a set position of the electronic device, the distances between the magnetic components of different accessories and the linear Hall sensor are different from each other, or the relative positions between the magnetic components and the linear Hall sensor are different, so that the linear Hall sensor can output different magnetic field intensity characterization data. The magnetic field intensity characterization data can be voltage data or current data. In an embodiment, the voltage data is taken as an example for description. According to the accessory identification schematic diagram shown in FIG. 3, if the magnet 10 in the first accessory 1 is, for example, located on the left of the (linear) Hall sensor 20 of the electronic device 2, and the distance between the magnet 10 and the linear Hall sensor 20 is 2 mm, the linear Hall sensor 20 detects that the magnetic field intensity thereof is −2.5 GS, and the output voltage value is 500 mV. As to the second accessory 3 in FIG. 4, the magnet 10 therein is located above the linear Hall sensor 20 of the electronic device 2, and the distance between the magnet 10 and the linear Hall sensor 20 is 0 mm, thus the linear Hall sensor 20 detects that the magnetic field intensity thereof is 0 GS, and the output voltage value is 1500 mV. As to the third accessory 4 in FIG. 5, the magnet 10 thereof is located on the right of the linear Hall sensor 20 of the electronic device 2, and the distance between the magnet 10 and the linear Hall sensor 20 is 3 mm, thus the linear Hall sensor 20 detects that the magnetic field intensity thereof is 3 GS, and the output voltage value is 3000 mV. The linear Hall sensor can be integrated with an analog-to-digital converter (ADC), so that a voltage value representing a magnetic field intensity can be directly obtained, and if the ADC is not integrated, analog-to-digital conversion can be performed by the ADC to obtain the digital voltage data. In addition, in order to prevent the detection data from being interfered by other magnetic substances, a physical anti-magnetic interference means can also be used during detection to ensure the accuracy of the detection data.

In some embodiments, before generating the target magnetic field intensity characterization data by the magnetic field intensity detection element in response to the magnetic field intensity of the magnetic component in the target accessory, the method further includes: detecting the magnetic field intensity of the magnetic component in the target accessory in real time by the magnetic intensity detection element to obtain respective first voltage data; and if the first voltage data is within a preset voltage threshold range, determining that the target accessory is located at a preset target position of the electronic device.

In an embodiment, a fixed position can be disposed on the electronic device, and when detection is required, the target accessory is placed at the fixed position, so that different accessories have the same reference point. In this embodiment, whether each accessory is at the fixed position is detected by the linear Hall sensor, so that a magnetic field intensity of each magnet in an accessory that needs to be used in a related scenario at the fixed position can be detected in advance, and a respective voltage value will output, so as to obtain a voltage threshold range. When the accessory identification is needed, the magnetic field intensity of the magnet in the target accessory is detected in real time, and when the voltage value representing the magnetic field intensity of the magnet is within the voltage threshold range, it is determined that the magnet is at the preset fixed position of the electronic device. Meanwhile, in this embodiment, only when the target accessory is at the fixed position, the acquired magnetic field intensity characterization data is subsequently matched, and matched with the voltage threshold range, so that the data that does not belong to the target magnetic field intensity characterization data can be screened out, thereby improving the accuracy of subsequent matching data.

In some other embodiments, before generating the target magnetic intensity characterization data by the magnetic intensity detection element in response to the magnetic intensity of the magnetic component in the target accessory, the method further includes the following steps. The magnetic field intensity of the reference magnetic component in the reference accessory at the target position is detected by the magnetic field intensity detection element to obtain reference magnetic field intensity characterization data. If the reference magnetic field intensity characterization data meets the magnetic field intensity characterization data range associated with the reference magnetic component, the target magnetic field intensity characterization data will be generated by the magnetic field intensity detection element in response to the magnetic component in the target accessory.

In an embodiment, in order to ensure the accuracy and reliability of the detected magnetic intensity characterization data, before the magnetic intensity detection is performed, the linear Hall sensor can be verified. That is, a reference accessory is selected, the magnetic intensity detection is performed on the reference magnetic component in the reference accessory by the linear Hall sensor, and then the output reference magnetic intensity characterization data is matched with the magnetic intensity characterization data range associated with the reference magnetic component. If the reference magnetic intensity characterization data is within the magnetic intensity characterization data range, it is determined that the verification succeeds, and a subsequent operation of generating target magnetic intensity characterization data in response to the magnetic intensity of the magnetic component in the target accessory can be performed.

Further, in some embodiments, when there are a plurality of target magnetic field intensity characterization data, said generating the target magnetic field intensity characterization data by the magnetic field intensity detection element in response to the magnetic field intensity of the magnetic component in the target accessory includes the following steps. The magnetic field intensity of the magnetic component in the target accessory in different orientations are detected by the magnetic intensity detection element to obtain a plurality of target magnetic intensity characterization data. And/or, the magnetic field intensity of the magnetic component in the target accessory in the same orientation are detected by the magnetic intensity detection element according to a preset number of times of detection to obtain a plurality of target magnetic intensity characterization data.

In an embodiment, when the target accessory is at the preset fixed position, one or more magnetic field intensity characterization data can be obtained through detection. That is, the detection can be performed once by the linear Hall sensor and to obtain one magnetic field intensity characterization data. In order to improve detection accuracy, the detection can also be performed multiple times to obtain a plurality of magnetic field intensity characterization data. When a plurality of magnetic field intensity characterization data need to be obtained, the magnetic field intensity of the magnetic component in the same orientation can be detected a preset number of times by the linear Hall sensor, or the magnetic field intensity of the magnetic component may be detected from multiple orientations, or the two types of detection may be combined. The target accessories in multiple orientations are all at the preset fixed positions, so that the target accessory can be rotated at a preset angle.

Step 102: the target magnetic field intensity characterization data is matched with the preset accessory index table.

In an embodiment, when obtaining the magnetic field intensity characterization data which is detected when the target accessory is located at the preset fixed position of the electronic device, the magnetic field intensity characterization data can be queried in the preset accessory index table. The accessory index table includes the mapping relationship between the magnetic field intensity characterization data range and the accessory identification information. For example, the magnetic field intensity characterization data range is [498, 502], corresponding to the first accessory.

In some embodiments, when there are a plurality of target magnetic field intensity characterization data, said matching the target magnetic field intensity characterization data with a preset accessory index table includes the following steps. The plurality of target voltage data are screened to obtain a plurality of first target voltage data; the mean value of the plurality of first target voltage data is calculated to obtain second target voltage data; and the second target voltage data is matched with the preset accessory index table.

In an embodiment, when there are a plurality of magnetic field intensity characterization data detected when the target accessory is located at the preset fixed position of the electronic device, the obtained magnetic field intensity characterization data can be screened to select a preset quantity of target magnetic field intensity characterization data or select target magnetic field intensity characterization data with high reference. Then the mean value of the first target magnetic field intensity characterization data obtained through screening is calculated to obtain the second target magnetic field intensity characterization data. Finally, the second target magnetic field intensity characterization data is queried in the preset accessory index table. Optionally, each of the first target magnetic field intensity characterization data obtained through screening can be directly matched with the accessory index table, and the magnetic field intensity characterization data range with the maximum times of occurrence in the matching result shall take effect.

Further, in some embodiment, said screening the plurality of target voltage data to obtain the plurality of first target voltage data includes the following steps. A sum of the absolute values of the differences between each target voltage data and other target voltage data is calculated, so that a plurality of sums of absolute values can be obtained. Each of the sums of absolute values is compared with a preset threshold and then, if there is a sum of target absolute values greater than the threshold, the respective target voltage data would be removed, to obtain the plurality of first target voltage data.

In this embodiment, in order to guarantee the reference of the calculation result of the mean value, the data having a large difference from other target magnetic field intensity characterization data in the plurality of target magnetic field intensity characterization data can be screened out. For example, each target magnetic field intensity characterization data is subtracted from other target magnetic field intensity characterization data, then the absolute value of the difference corresponding to each piece of target magnetic field intensity characterization data is summed to obtain a plurality of sums of absolute values of the differences, then the sums of the absolute values of the differences are each compared with a preset threshold, and finally, the target magnetic field intensity characterization data corresponding to a sum of the absolute values of the differences greater than the threshold is removed. Optionally, the target magnetic field intensity characterization data corresponding to the maximum sum of the target absolute values among the sums of the absolute values of the differences is removed.

Further, in some other embodiments, after matching the target magnetic field intensity characterization data with the preset accessory index table, the method further includes the following steps. If the target magnetic field intensity characterization data fails to match the respective magnetic field intensity characterization data range in the accessory index table, prompt information would be outputted to indicate that the target accessory is in an abnormal state.

In an embodiment, if the corresponding magnetic field intensity characterization data range is not matched with the accessory index table, it indicates that the accessory can be damaged or the detected magnetic field intensity characterization data is abnormal (for example, interfered by other magnetic objects), and prompt information would be outputted to indicate that the accessory is in an abnormal state can be output, and remind the related personnel to conduct abnormality investigation.

Step 103: the accessory identification information corresponding to the matched magnetic field intensity characterization data range is determined as the identification information of the target accessory.

In an embodiment, when the magnetic intensity characterization data, which is detected when the target accessory is located at the fixed position of the electronic device, is matched with the respective magnetic intensity characterization data range in the accessory index table, the accessory identification information corresponding to the intensity characterization data range can be determined as the identification information of the target accessory. For example, when the intensity characterization data range [1498, 1502] is matched with the accessory index table according to the voltage value of 1500 mV, the target accessory is determined to be the second accessory. For the similar reasons, any accessed normal accessory can be identified according to different voltage values. Therefore, according to the accessory identification method based on magnetic intensity detection according to this embodiment, whether an accessory is accessed or not can be detected, and various types of accessories can be identified. Further, both the magnetic intensity detection element and the magnetic component can be installed in a hidden manner, so that the association information of the accessory is not easily to be stolen, which is beneficial to guaranteeing the information security of the accessory. Meanwhile, the hardware implementation of the identification method is simple, which only needs to provide a magnetic intensity detection element at the electronic device side and provide a magnetic component at the accessory side, so that the overall cost is low, without the requirement to occupy too much volume. In addition, the determination of the magnetic detection element such as a Hall sensor has high precision (up to +/−0.05 mm), so that identification of various accessories can be achieved within a small size.

Based on the technical solutions of the above embodiments of the present disclosure, when it is detected that the target accessory is located at the preset target position of the electronic device, the target magnetic intensity characterization data is generated by the magnetic intensity detection element in response to the magnetic intensity of the magnetic component in the target accessory. The magnetic intensity characterization data includes voltage data. The target magnetic intensity characterization data is matched with the preset accessory index table. The accessory index table includes a mapping relationship between a magnetic intensity characterization data range and accessory identification information. The accessory identification information corresponding to the matched magnetic intensity characterization data range is determined to be the identification information of the target accessory. According to the implementation of the technical solutions of the present disclosure, the magnetic field intensity of the magnetic component in the accessory is detected to obtain the corresponding magnetic intensity characterization data. Then the identification information of the accessory can be obtained by querying in the table according to the magnetic intensity characterization data, so that the identification information of the accessory can be hidden in the identification manner, thereby achieving the security of the accessory information. Meanwhile, compared with the related art, the present disclosure only needs the magnetic intensity detection element installed on the electronic device and the magnetic component installed on the accessory, without excessive hardware resources, thereby effectively saving the hardware resource cost.

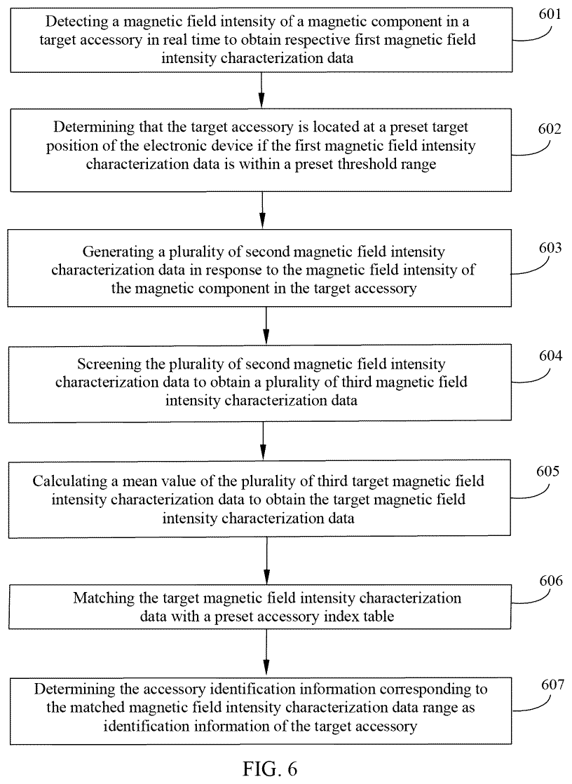

The method in FIG. 6 is a detailed accessory identification method according to an embodiment of the present disclosure. The method includes the following steps.
Step 601: a magnetic field intensity of a magnetic component in a target accessory is detected in real time to obtain respective first magnetic field intensity characterization data.
Step 602: the target accessory is determined to be located at a preset target position of the electronic device if the first magnetic field intensity characterization data is within a preset threshold range.
Step 603: a plurality of second magnetic field intensity characterization data are generated in response to the magnetic field intensity of the magnetic component in the target accessory.
Step 604: the plurality of second magnetic field intensity characterization data are screened to obtain a plurality of third magnetic field intensity characterization data.
Step 605: a mean value of the plurality of third target magnetic field intensity characterization data is calculated to obtain the target magnetic field intensity characterization data.
Step 606: the target magnetic field intensity characterization data is matched with a preset accessory index table.
Step 607: the accessory identification information corresponding to the matched magnetic field intensity characterization data range is determined as identification information of the target accessory.

It should be understood that the sequence number of each step of the present disclosure does not indicate an execution sequence of the steps, and the execution sequence of each step should be determined based on a function and internal logic thereof and should not constitute a unique limitation to an implementation process of the present disclosure.

Based on the technical solutions of the above embodiments of the present disclosure, by detecting the magnetic field intensity of the magnetic component in the target accessory in real time, when the voltage value representing the magnetic field intensity thereof is within the preset voltage threshold range, it is determined that the target accessory is at the preset fixed position of the electronic device, a plurality of voltage values detected when the target accessory is at the fixed position are acquired. Then the acquired voltage values are screened to select a preset number of target voltage values or select a target voltage value with high reference, then the mean value of the target voltage values obtained by screening is calculated. Finally, the target voltage mean value is queried in the preset accessory index table. If the corresponding voltage range is matched with the accessory index table, the accessory identification information corresponding to the voltage range can be determined to be the identification information of the target accessory. Through implementation of the technical solutions of the present disclosure, whether accessories are accessed or not can be detected, and different types of accessories can be identified. Further, the magnetic intensity detection element and the magnetic component can both be installed in a hidden manner, so that association information of the accessories is not easy to be stolen, thereby achieving the security of the accessory information. Meanwhile, the hardware implementation of the identification method is simple, which only needs to provide a magnetic intensity detection element at the electronic device side and provide a magnetic component at the accessory side, so that the overall cost is low, without the requirement to occupy too much volume. In addition, the determination of the magnetic detection element such as a Hall sensor has high precision, so that identification of various accessories can be achieved within a small size.

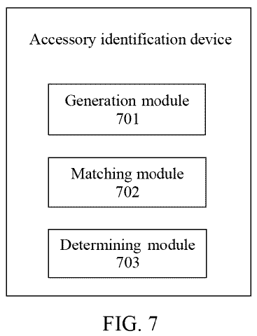

FIG. 7 is a schematic diagram of an accessory identification device, which is applied to an electronic device, according to an embodiment of the present disclosure. The accessory identification device mainly includes a generation module 701, a matching module 702 and a determining module 703.

The generation module 701 is configured to generate target magnetic field intensity characterization data by a magnetic field intensity detection element in response to a magnetic field intensity of a magnetic component in the target accessory when it is detected that the target accessory is located at a preset target position of the electronic device. The magnetic field intensity characterization data includes voltage data.

The matching module 702 is configured to match the target magnetic field intensity characterization data with a preset accessory index table. The accessory index table includes a mapping relationship between a magnetic field intensity characterization data range and accessory identification information.

The determining module 703 is configured to determine accessory identification information corresponding to the matched magnetic field intensity characterization data range as identification information of the target accessory.

In some embodiments, before performing the function of generating the target magnetic field intensity characterization data by the magnetic field intensity detection element in response to the magnetic field intensity of the magnetic component in the target accessory, the generation module is further configured to: detect the magnetic field intensity of the magnetic component in the target accessory in real time by the magnetic intensity detection element to obtain respective first voltage data; and if the first voltage data is within a preset voltage threshold range, determine that the target accessory is located at a preset target position of the electronic device.

In some other embodiments, before performing the function of generating the target magnetic field intensity characterization data by the magnetic field intensity detection element in response to the magnetic field intensity of the magnetic component in the target accessory, the generation module is further configured to: detect a magnetic field intensity of a reference magnetic component in a reference accessory at a target position by a magnetic field intensity detection element to obtain reference magnetic field intensity characterization data; and if the reference magnetic field intensity characterization data meets a magnetic field intensity characterization data range associated with the reference magnetic component, generate target magnetic field intensity characterization data in response to the magnetic field intensity of the magnetic component in the target accessory.

Further, in some embodiments, there are a plurality of target magnetic field intensity characterization data, and the generation module is configured to: detect the magnetic field intensity of the magnetic component in the target accessory when the target accessory is in different orientations by the magnetic intensity detection element to obtain a plurality of target magnetic intensity characterization data; and/or detect the magnetic field intensity of the magnetic component in the target accessory in the same orientation according to a preset number of times of detection to obtain a plurality of target magnetic intensity characterization data.

In some embodiments, when there are a plurality of target magnetic field intensity characterization data, the matching module is configured to: screen the plurality of target voltage data to obtain a plurality of first target voltage data; calculate a mean value of the plurality of first target voltage data to obtain second target voltage data; and match the second target voltage data with the preset accessory index table.

Further, in some embodiments, when performing the function of screening the plurality of target voltage data to obtain the plurality of first target voltage data, the matching module is configured to: calculate a sum of absolute values of differences between each target voltage data and other target voltage data to obtain a plurality of sums of absolute values; compare each sum of absolute values with a preset threshold; and if there is a sum of target absolute values greater than the threshold, remove the respective target voltage data to obtain the plurality of first target voltage data.

Further, in some embodiments, the accessory identification apparatus further includes an output module. The output module is configured to output prompt information indicating that the target accessory is in an abnormal state if the target magnetic field intensity characterization data does not match a corresponding magnetic field intensity characterization data range in the accessory index table.

It should be noted that all the accessory identification methods in the foregoing embodiments can be implemented by the accessory identification device according to embodiments of the present disclosure. Those skilled in the art can clearly understand that, for ease and brevity of description, for a specific working process of the accessory identification device described in embodiments of the present disclosure can be referred to a corresponding process of the foregoing method embodiments, which will not be described in detail herein again.

Based on the technical solutions of embodiments of the present disclosure, when it is detected that the target accessory is located at the preset target position of the electronic device, the target magnetic intensity characterization data is generated by the magnetic intensity detection element in response to the magnetic intensity of the magnetic component in the target accessory. The magnetic intensity characterization data includes voltage data. The target magnetic intensity characterization data is matched with a preset accessory index table. The accessory index table includes a mapping relationship between the magnetic intensity characterization data range and the accessory identification information. The accessory identification information corresponding to the matched magnetic intensity characterization data range is determined to be the identification information of the target accessory. According to the implementation of the technical solutions of the present disclosure, the magnetic field intensity of the magnetic component in the accessory is detected to obtain the corresponding magnetic intensity characterization data. Then the identification information of the accessory can be obtained by querying in the table according to the magnetic intensity characterization data, so that the identification information of the accessory can be hidden by the identification, thereby achieving the information security of the accessory. Meanwhile, compared with the related art, the present disclosure only needs the magnetic intensity detection element installed on the electronic device and the magnetic component installed on the accessory, without excessive hardware resources, thereby effectively saving the hardware resource cost.

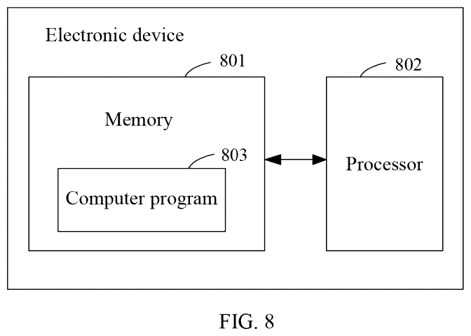

FIG. 8 is a schematic structural diagram of an electronic device according to an embodiment of the present disclosure. The electronic device can be configured to implement the accessory identification method in the foregoing embodiments. The electronic device mainly includes a memory 801, a processor 802, and a computer program 803 stored on the memory 801 and executable on the processor 802.

The memory 801 and the processor 802 communicate with each other. When executing the computer program 803, the processor 802 implements the methods in the foregoing embodiments. There can be one or more processors. The electronic device can be a mobile phone, a computer, a household appliance, etc., and the corresponding accessory can be an earphone, a charger, a motor, etc.

The memory 801 can be a high-speed random access memory (RAM), or can be a non-volatile memory, such as a magnetic disk memory. The memory 801 is configured to store executable program codes. The processor 802 is coupled to the memory 801.

Further, an embodiment of the present disclosure further provides a computer-readable storage medium. The computer-readable storage medium can be arranged in the foregoing electronic devices. The computer-readable storage medium can be the memory in an embodiment shown in FIG. 8.

The computer readable storage medium stores a computer program, and the processor, when executing the program, implements the accessory identification method in the foregoing embodiments. Further, the computer readable storage medium can be a USB flash disk, a mobile hard disk, a read-only memory (ROM), a RAM, a magnetic disk, an optical disk, or any other medium that can store program codes.

In above embodiments provided in the present disclosure, it should be understood that the disclosed device and method can be implemented in other manners. For example, the above device embodiments described above are merely illustrative. For example, the division of modules is merely a kind of logical function division, and there can be other division manners in actual implementations. For example, a plurality of modules or components can be combined with or integrated into another system, or some features can be ignored, or cannot be performed. Alternatively, the coupling or direct coupling or communication connection shown or discussed with respect to each other can be an indirect coupling or communication connection through some interfaces, devices or modules, and can be in an electrical, mechanical or other form.

The modules described as separate components can be or not be physically separated from each other. The components displayed as modules can be or not be physical modules, that is, can be located in one place, or can be distributed to multiple network modules. Some or all of the modules can be selected according to actual needs to achieve the purpose of the solutions of embodiments of the present disclosure.

In addition, the functional modules in embodiments of the present disclosure can be integrated into one processing module, or each module can be physically individual, or two or more modules can be integrated into one module. The foregoing integrated modules can be implemented in a form of hardware, or can be implemented in a form of a software function module.

If the integrated module is implemented in a form of a software function module and is sold or used as an independent product, the integrated module can be stored in a computer-readable storage medium. Based on such comprehension, the technical solutions of the present disclosure essentially or a part contributing to the prior art or all or part of the technical solutions can be embodied in a form of a software product. The computer software product is stored in a readable storage medium and includes instructions for causing a computer device (which can be a personal computer, a server, or a network device, etc.) to perform all or part of the steps of the methods in embodiments of the present disclosure. The above storage medium includes: various media that can store program codes, such as a USB flash drive, a mobile hard disk, a ROM, a RAM, a magnetic disk, or an optical disk.

It should be noted that, to simplify the description, the foregoing method embodiments are all described as a series of action combinations. Whereas those skilled in the art should know that the present disclosure is not limited by the described action sequence, because according to the present disclosure, some steps can be performed in other sequences or simultaneously. In addition, those skilled in the art should also know that all embodiments described in the specification are just preferred embodiments, and the involved actions and modules are not indispensable in the present disclosure.

In the above embodiments, the description of each embodiment has a focus, and a certain part that is not described in detail in a certain embodiment, can be referred to in related descriptions in other embodiments.

The above describes the accessory identification method and device and the storage medium according to the present disclosure, and for those skilled in the art, according to the thoughts of embodiments of the present disclosure, changes can be made in the specific implementation and the application scope. As above, the content of the present disclosure should not be construed as limiting the present disclosure.

What is claimed is:

1. An accessory identification method, applied to an electronic device provided with a magnetic field intensity detection element, the accessory identification method comprising:
generating target magnetic intensity characterization data by the magnetic intensity detection element in response to a magnetic intensity of a magnetic component in a target accessory, when it is detected that the target accessory is located at a preset target position of the electronic device, wherein the magnetic intensity characterization data comprise voltage data;
matching the target magnetic field intensity characterization data with a preset accessory index table, wherein the accessory index table comprises a mapping relationship between a magnetic field intensity characterization data range and accessory identification information; and
determining accessory identification information corresponding to a matched magnetic field intensity characterization data range as identification information of the target accessory.

2. The accessory identification method as described in claim 1, wherein prior to generating the target magnetic field intensity characterization data by the magnetic field intensity detection element in response to the magnetic field intensity of the magnetic component in the target accessory, the method further comprises:
detecting the magnetic field intensity of the magnetic component in the target accessory in real time by the magnetic field intensity detection element to obtain respective first voltage data; and
determining that the target accessory is located at a preset target position of the electronic device when the first voltage data are within a preset voltage threshold range.

3. The accessory identification method as described in claim 1, wherein subsequent to matching the target magnetic field intensity characterization data with the preset accessory index table, the method further comprises:
outputting prompt information that the target accessory is in an abnormal state when the target magnetic field intensity characterization data does not match a respective magnetic field intensity characterization data range in the accessory index table.

4. The accessory identification method as described in claim 1, wherein a plurality of target magnetic field intensity characterization data is provided, and said matching the target magnetic field intensity characterization data with the preset accessory index table comprises:
screening a plurality of target voltage data to obtain a plurality of first target voltage data;
calculating an average value of the plurality of first target voltage data to obtain second target voltage data; and
matching the second target voltage data with the preset accessory index table.

5. The accessory identification method as described in claim 4, wherein said screening the plurality of target voltage data to obtain the plurality of first target voltage data comprises:
calculating to obtain a sum of absolute values of differences between each of the plurality of target voltage data and the remaining target voltage data;
comparing each of the sums of absolute values with a preset threshold; and
removing respective target voltage data to obtain the plurality of first target voltage data when existing at least one sum of target absolute values greater than the preset threshold.

6. The accessory identification method as described in claim 4, wherein the magnetic field intensity detection element comprises a Hall sensor, and said generating target magnetic field intensity characterization data by the magnetic field intensity detection element in response to the magnetic field intensity of the magnetic component in the target accessory comprises:
detecting magnetic field intensity of the magnetic components in the target accessory by the Hall sensor when the target accessory is in different orientations to obtain the plurality of target magnetic field intensity characterization data; and/or
detecting a magnetic field intensity of a magnetic component in the target accessory in a same orientation by the Hall sensor according to preset times of detection to obtain the plurality of target magnetic field intensity characterization data.

7. The accessory identification method as described in claim 1, wherein prior to the generating target magnetic field intensity characterization data by the magnetic field intensity detection element in response to the magnetic field intensity of the magnetic component in the target accessory, the method further comprises:
detecting a magnetic field intensity of a reference magnetic component in a reference accessory at the target position by on the magnetic field intensity detection element to obtain reference magnetic field intensity characterization data; and
performing said generating target magnetic field intensity characterization data by the magnetic field intensity detection element in response to the magnetic field intensity of the magnetic component in the target accessory, when the reference magnetic field intensity characterization data satisfies a magnetic field intensity characterization data range associated with the reference magnetic component.

8. An accessory identification device applied to an electronic device provided with a magnetic field intensity detection element, the accessory identification device comprising:
a generation module configured to generate target magnetic field intensity characterization data by the magnetic field intensity detection element in response to a magnetic field intensity of a magnetic component in a target accessory, when it is detected that a target accessory is located at a preset target position of the electronic device, wherein the magnetic field intensity characterization data comprise voltage data;
a matching module configured to match the target magnetic field intensity characterization data with a preset accessory index table, wherein the accessory index table comprises a mapping relationship between a magnetic field intensity characterization data range and accessory identification information; and
a determining module configured to determine accessory identification information corresponding to a matched magnetic field intensity characterization data range as identification information of the target accessory.

9. A computer readable storage medium storing a computer program, wherein the computer program, when executed by a processor, implements the steps of the accessory identification method as described in claim 1.
